(19) United States
(12) Patent Application Publication
(10) Pub. No.: US 2025/0065594 A1
(43) Pub. Date: Feb. 27, 2025

(54) THERMALLY CONDUCTIVE AND VIBRATION-ISOLATING INTERFACE MATERIAL

(71) Applicant: INNOVUSION (SUZHOU) CO., LTD., SUZHOU (CN)

(72) Inventors: Guojun Liu, SUZHOU (CN); Lirui Lu, SUZHOU (CN); Siwei Luo, SUZHOU (CN); Junwei Bao, SUZHOU (CN)

(73) Assignee: INNOVUSION (SUZHOU) CO., LTD., SUZHOU, JS (CN)

(21) Appl. No.: 18/714,046

(22) PCT Filed: Nov. 28, 2022
(86) PCT No.: PCT/IB2022/061461

§ 371 Date: May 28, 2024

(30) Foreign Application Priority Data
Nov. 29, 2021 (CN) 202111438971.0

(51) Int. Cl. B32B 3/18; B32B 5/18; B32B 7/12; B32B 9/00; B32B 9/04; B32B 25/20; B32B 27/30

(52) U.S. Cl. CPC B32B 3/18; B32B 5/18; B32B 7/12; B32B 9/007; B32B 9/045; B32B 25/20; B32B 27/308; B32B 2266/0207; B32B 2307/302; B32B 2307/7376; B32B 2313/04; B32B 2319/00; B32B 2367/00

(57) ABSTRACT

The present invention discloses a thermally conductive and vibration-isolating interface material, comprising thermally conductive strips in multiple groups of arrays, wherein the thermally conductive strip comprises an inner core on the inside, the outside of the inner core is covered with a back adhesive layer, the outside of the back adhesive layer is adhered with a heat transfer layer, the outside of the heat transfer layer is covered with an insulating layer, and a thermally conductive pad is provided on the outer side of the thermally conductive strip, with the area of the thermally conductive pad being greater than the surface area of the single thermally conductive strip.

### CROSS-REFERENCE TO RELATED APPLICATIONS

This application claims priority to Chinese Patent Application No. 202111438971.0, filed Nov. 29, 2021, entitled “AN INTERFACE MATERIAL FOR HEAT CONDUCTION AND VIBRATION ISOLATION,” the content of which is hereby incorporated by reference in its entirety.

### TECHNICAL FIELD

The present invention relates to the field of thermally conductive foam processing, and in particular to a thermally conductive and vibration-isolating interface material.

### BACKGROUND

Under the operating condition of having a shock-absorbing structure or requiring vibration isolation, it is also required to achieve heat dissipation through conduction for an apparatus, so there is a need for an interface material that can achieve both vibration isolation and heat transfer. The existing graphite-coated foam composite materials basically meet the operating condition, but have deficiencies in vibration isolation performance, heat resistance performance, heat transfer performance and mass production manufacturability.

A thermally conductive graphite foam in the invention with publication number of CN 205818554 U can effectively prevent the occurrence of electric leakage due to the falling of graphite powder into the gap of a machine, which can effectively improve the working efficiency in practical and solve the problem of abnormality due to the falling of graphite powder, but there are still the following problems.

1. The commonly used intermediate foam material is PE, which cannot withstand high temperature up to 110° C. and has low rebound rate at high temperature.

2. The interface contact thermal resistance is large. In one commonly used method, the graphite-coated foam has no back adhesive on its outer side and is in contact with the interface by pressure, and there are many microscopic air gaps at the contact interface, which increases the contact thermal resistance. In another commonly used method, the adhesion is achieved by means of common back adhesive on the outer surface, which increases the contact thermal resistance due to the poor heat transfer and the large thermal resistance of the back adhesive.

3. The heat transfer resistance is large. The heat transfer path of conventional graphite-coated foam is the surface graphite, because the thickness dimension of graphite is usually limited to be 100 μm or less, which has small heat transfer cross-sectional area and large heat transfer resistance.

4. The mass production manufacturability is poor. This cannot meet the needs of mass production, because the graphite foam will be scattered during assembly, which is not convenient for mass production.

### SUMMARY

The objective of the present invention is to propose a thermally conductive and vibration-isolating interface material in order to overcome the shortcomings in the prior art.

In order to achieve the above objective, the present invention adopts the following technical solution: a thermally conductive and vibration-isolating interface material, comprising thermally conductive strips in multiple groups of arrays, wherein

the thermally conductive strip comprises an inner core on the inside, the outside of the inner core is covered with a back adhesive layer, the outside of the back adhesive layer is adhered with a heat transfer layer, and the outside of the heat transfer layer is covered with an insulating layer; and

a thermally conductive pad is provided on the outer side of the thermally conductive strip, with the area of the thermally conductive pad being greater than the surface area of the single thermally conductive strip.

As a further description of the above technical solution, the thermally conductive pad covers one of or both of the upper and lower sides of the thermally conductive strip, and the outside of the thermally conductive pad is connected to multiple groups of thermally conductive strips simultaneously.

As a further description of the above technical solution, a gap of a certain distance is provided between adjacent thermally conductive strips.

As a further description of the above technical solution, the heat transfer layer is a graphite film or a graphene film.

As a further description of the above technical solution, the inner core is a foamed silicone material with high porosity.

As a further description of the above technical solution, the thermally conductive pad is an acrylic-based thermally conductive pad and has a thermal conductivity greater than 3 W/(m·K) and a hardness less than 30 HA.

As a further description of the above technical solution, the heat transfer layer has a thickness of 17 μm to 100 μm.

As a further description of the above technical solution, the thermally conductive pad has a thickness of 0.3 mm to 3 mm.

As a further description of the above technical solution, the thermally conductive pad is self-adhesive.

As a further description of the above technical solution, the material of the insulating layer is PET (polyethylene terephthalate).

The present invention has the advantages as follows.

1. According to the present invention, the width of the thermally conductive strip can be determined according to the size and the thermal conductivity of the interface material, and a gap is reserved between the strips to accommodate the compressive deformation in order to prevent the interference between the strips during compression, thereby ensuring good compressibility and vibration isolation. The thermally conductive interface material is composed of multiple arrays, thereby leaving more heat transfer channels to enhance the vertical heat transfer performance of the interface material.

2. According to the present invention, the material of the inner core is foamed silicone with high porosity, which can withstand a high temperature of 120° C. without reducing the rebound rate as compared with the original PE material, and has small compression stress, large compression rate and large rebound rate, thereby ensuring the compressibility, the compression stress, the vibration isolation and the rebound rate of the interface material.

3. According to the present invention, the self-adhesive thermally conductive pad is bonded to the surface of the thermally conductive strip array, whereas the thermally conductive pad is a self-adhesive acrylic-based or silicone-based thermally conductive pad which has a thermal conductivity greater than 3 W/(m·K) and a hardness less than 30 HA, thereby reducing the interface contact thermal resistance between the interface material and the apparatus, enhancing the heat transfer performance in the horizontal direction and improving the overall reliability of the interface material. The entire interface material is coated or bonded by means of the thermally conductive pad as a whole, thus preventing scattering and optimizing the bonding manufacturability. During the production process of the thermally conductive interface material, it is more convenient to paste the thermally conductive pad than to paste the thermally conductive double-sided tape on the thermally conductive foam strip array, and it is easier to achieve the mass production process.

4. According to the present invention, the thermally conductive pad is a self-adhesive acrylic-based thermally conductive pad, which withstands a high temperature of 120° C. or above and has higher reliability as compared with the double-sided tape or the back adhesive.

### BRIEF DESCRIPTION OF THE DRAWINGS

FIG. 1 is a cross-sectional view of a thermally conductive and vibration-isolating interface material according to the present invention; and

FIG. 2 is a schematic diagram of part A of the thermally conductive and vibration-isolating interface material in FIG. 1 according to the present invention.

### LIST OF REFERENCE NUMERALS

1. thermally conductive strip; 2. inner core; 3. back adhesive layer; 4. heat transfer layer;

5. insulating layer; and 6. thermally conductive pad.

### DETAILED DESCRIPTION OF EMBODIMENTS

The technical solutions in the embodiments of the present invention will be clearly and completely described hereinafter with reference to the drawings in the embodiments of the present invention, and it is obvious that the described embodiments are some of, but not all, the embodiments of the present invention. All other embodiments obtained by those ordinary skilled in the art based on the embodiments in the present invention without any creative effort shall fall within the scope of protection of the present invention.

In the description of the present invention, it is noted that the orientation or the relative location indicated by the terms “center”, “upper”, “lower”, “left”, “right”, “vertical” “horizontal”, “inner”, “outer”, etc. is based on the orientation or relative location shown in the accompanying drawings for ease of describing the present invention and simplifying the description only, rather than indicating or implying that the referred device or element must have a particular orientation or be constructed and operated in a particular orientation, and thus should not to be interpreted as limiting the present invention. The terms “first”, “second” and “third” are merely for the purpose of description and should not be construed as indicating or implying the relative importance, in addition, the terms “mounting”, “connecting” and “connection” should be interpreted in a broad sense, unless otherwise explicitly defined and limited, and for example, may be interpreted as fixed connection, detachable connection or integrated connection; may be interpreted as mechanical connection or electrical connection; may be interpreted as direct connection or indirect connection via an intermediate medium; may be interpreted as internal interconnection of two elements. For those ordinary skilled in the art, the specific meaning of the above terms in the present invention should be construed according to specific circumstances.

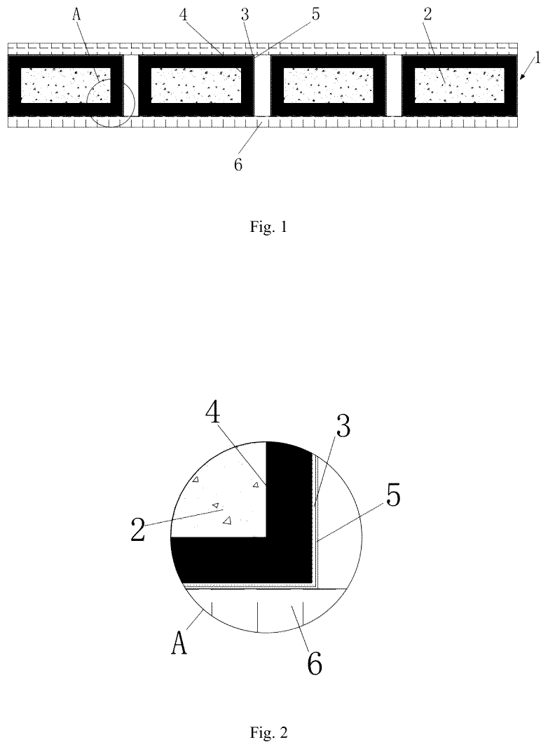

Referring to FIGS. 1-2, the present invention provides an embodiment: a thermally conductive and vibration-isolating interface material, comprising thermally conductive strips 1 in multiple groups of arrays;

the thermally conductive strip 1 comprises an inner core 2 on the inside, the outside of the inner core 2 is covered with a back adhesive layer 3, the outside of the back adhesive layer 3 is adhered with a heat transfer layer 4, and the outside of the heat transfer layer 4 is covered with an insulating layer 5;

a thermally conductive pad 6 is provided on the outer side of the thermally conductive strip 1, with the area of the thermally conductive pad 6 being greater than the surface area of a single thermally conductive strip 2.

The whole interface material is composed of thermally conductive strips 1 in multiple groups of arrays and thermally conductive pads 6 adhered to both of or one of the upper and lower sides of the thermally conductive strips, and a gap of a certain distance is provided between two adjacent groups of thermally conductive strips 1, which can accommodate the compressive deformation of the thermally conductive strips 1 and prevent the interference between adjacent thermally conductive strips 1. The material of the inner core 2 of the thermally conductive strip 1 is foamed silicone with high porosity, which has small compression stress, large compression rate and large rebound rate, thereby ensuring good compressibility and vibration isolation. In addition, the presence of the gaps allows heat to pass through the gaps, thereby the vertical heat transfer performance of the interface material is improved. Since the material of the inner core 2 is foamed silicone that withstands a high temperature of 120° C., the rebound rate can be maintained at a temperature of 110° C.

Further, the thermally conductive pad 6 covers one of or both of the upper and lower sides of the thermally conductive strip 2, and the outside of the thermally conductive pad 6 is connected to multiple groups of thermally conductive strips 1 simultaneously.

Further, a gap of a certain distance is provided between the adjacent thermally conductive strips 1.

Further, the heat transfer layer 4 is a graphite film or a graphene film, which has good thermal conductivity.

Further, the inner core 2 is a foamed silicone material with high porosity, which has smaller compression stress, large compression rate and large rebound rate, so as to meet the requirement of high vibration isolation rate, and the foamed silicone can withstand high temperature up to 120° C.

Further, the thermally conductive pad 6 is a thermally conductive pad of acrylic or silicone base material and its thermal conductivity is greater than 3 W/(m·K) and hardness is less than 30 HA

The thermally conductive pad 6 has the self-adhesive acrylic or silicone base material, and the flexibility and gap-filling capability of the thermally conductive pad 6 can significantly reduce the contact thermal resistance between the interface material and the interface. The thermally conductive pad 6 increases the cross-sectional area of the heat transfer channel in the horizontal direction, and significantly reduces the heat transfer resistance in the horizontal direction. The separated thermally conductive strips 1 are coated or bonded by means of the thermally conductive pad 6 as a whole and thus will not be scattered after the outer protective film is torn off, thereby affecting the manufacturability of the interface material during use and the efficient mass production can be achieved. During the production process of the thermally conductive interface material, it is more convenient to paste the thermally conductive pad 6 than to paste the thermally conductive double-sided tape on the thermally conductive foam strip array, and it is easier to achieve the mass production process. Fourth, the thermally conductive pad can withstand a high temperature of 120° C. or above and has high reliability, while the double-sided tape or the back adhesive in the existing materials is difficult to satisfy the requirements of high temperature and high reliability.

Further, the heat transfer layer 4 has a thickness of 17 μm to 100 μm, and the heat transfer layer 4 is made of graphite or graphene material. Compared with the existing graphite or graphene with a thickness of 100 micrometers or less, the thickness of the graphite or graphene layer of the material is 17 μm to 100 μm, which has larger heat transfer area and smaller heat transfer resistance.

Further, the thermally conductive pad 6 has a thickness of 0.3 mm to 3 mm.

Further, the thermally conductive pad 6 is self-adhesive.

Further, the material of the insulating layer 5 is PET (polyethylene terephthalate).

In the working principle, when the product is in use, the whole interface material is composed of thermally conductive strips 1 in multiple groups of arrays and thermally conductive pads 6 adhered to both upper and lower sides of or between the thermally conductive strips. A gap of a certain distance is provided between two adjacent groups of thermally conductive strips 1, which can accommodate the compressive deformation of the thermally conductive strips 1 to prevent the interference between the adjacent thermally conductive strips 1. The material of the inner core 2 of the thermally conductive strips 1 is foamed silicone with high porosity, which has smaller compression stress, large compression rate and large rebound rate, thereby ensuring good compressibility and vibration isolation. In addition, the presence of the gaps allows heat to pass through the gaps thereby improving the vertical heat transfer performance of the interface material.

Since the material of the inner core 2 is foamed silicone that withstands a high temperature of 120° C., the rebound rate can be maintained at a temperature of 110° C.

The thermally conductive pad 6 has the self-adhesive acrylic or silicone base material, and the flexibility and gap-filling capability of the thermally conductive pad 6 can significantly reduce the contact thermal resistance between the interface material and the interface. The thermally conductive pad 6 increases the cross-sectional area of the heat transfer channel in the horizontal direction, and significantly reduces the heat transfer resistance in the horizontal direction. The separated thermally conductive strips 1 are coated or bonded by means of the thermally conductive pad as a whole, and thus will not be scattered after the outer protective film is torn off, thereby affecting the manufacturability of the interface material during use and the efficient mass production can be achieved. During the production process of the thermally conductive interface material, it is more convenient to paste the thermally conductive pad 6 than to paste the thermally conductive double-sided tape on the thermally conductive foam strip array, and it is easier to achieve the mass production process. The thermally conductive pad can withstand a high temperature of 120° C. or above and has higher reliability than the double-sided tape or the back adhesive in the existing materials.

Finally, it should be noted that the foregoing description is merely the preferred embodiments of the present invention and is not intended to limit the present invention. Although the present application has been illustrated in detail with reference to the foregoing embodiments, those skilled in the art can still modify the technical solution specified in the foregoing embodiments or make equivalent substitutions for some of the technical features therein. Any modifications, equivalent substitutions, improvements, etc. made within the spirit and principles of the present invention shall fall within the scope of protection of the present invention.

1-10. (canceled)

11. A thermally conductive and vibration-isolating interface material, comprising multiple thermally conductive strips in multiple groups, wherein:
a thermally conductive strip of the multiple thermally conductive strips comprises an inner core on the inside, the outside of the inner core is covered with a back adhesive layer, the outside of the back adhesive layer is adhered with a heat transfer layer, and the outside of the heat transfer layer is covered with an insulating layer; and
a thermally conductive pad is provided on the outer side of the thermally conductive strip, with the area of the thermally conductive pad being greater than the surface area of the-thermally conductive strip of the multiple thermally conductive strips.

12. The thermally conductive and vibration-isolating interface material of claim 11, wherein:
the thermally conductive pad covers one of or both of the upper and lower sides of the thermally conductive strip, and
the outside of the thermally conductive pad is connected to the multiple groups of the thermally conductive strips simultaneously.

13. The thermally conductive and vibration-isolating interface material of claim 11, wherein a gap of a certain distance is provided between adjacent thermally conductive strips of the multiple thermally conductive strips.

14. The thermally conductive and vibration-isolating interface material of claim 11, wherein the heat transfer layer is a graphite film or a graphene film.

15. The thermally conductive and vibration-isolating interface material of claim 11, wherein the inner core is a foamed silicone material with high porosity.

16. The thermally conductive and vibration-isolating interface material of claim 11, wherein the thermally conductive pad is an acrylic-based thermally conductive pad and has a thermal conductivity greater than 3 W/(m·K) and a hardness less than 30 HA.

17. The thermally conductive and vibration-isolating interface material of claim 11, wherein a thickness of the heat transfer layer ranges from 17 μm to 100 μm.

18. The thermally conductive and vibration-isolating interface material of claim 11, wherein a thickness of the thermally conductive pad ranges from 0.3 mm to 3 mm.

19. The thermally conductive and vibration-isolating interface material of claim 11, wherein the thermally conductive pad is self-adhesive.

20. The thermally conductive and vibration-isolating interface material of claim 11, wherein the material of the insulating layer is PET (polyethylene terephthalate).
